(19) United States
(12) Patent Application Publication
(10) Pub. No.: US 2026/0114018 A1
(43) Pub. Date: Apr. 23, 2026

(54) SEMICONDUCTOR DEVICE AND METHOD OF FORMING THE SAME

(71) Applicant: United Microelectronics Corp., Hsinchu (TW)

(72) Inventors: Jui Chen Chang, Kaohsiung City (TW); Bo Sing Lin, Tainan City (TW); Shih-Che Huang, Chiayi City (TW); Zhi Guang He, Tainan City (TW)

(73) Assignee: United Microelectronics Corp., Hsinchu (TW)

(21) Appl. No.: 18/939,559

(22) Filed: Nov. 7, 2024

(30) Foreign Application Priority Data
Oct. 22, 2024 (TW) 113140107

(51) Int. Cl. H01L 29/43; H01L 21/762; H01L 21/768

(52) U.S. Cl. CPC H10D 64/605; H10W 10/011; H10W 10/10; H10W 20/074

(57) ABSTRACT

A semiconductor device and a method of forming the same are provided. The semiconductor device includes a high resistance impedance layer between a gate and a first metal structure in a vertical direction, wherein the first metal structure comprises at least one equipotential first metal and at least one non-equipotential first metal, wherein the equipotential first metal and the high resistance impedance layer have the same potential, the non-equipotential first metal and high resistance impedance layer have not the same potential, and the non-equipotential first metal and the high resistance impedance layer do not overlap in the vertical direction, and a minimum distance, between an edge of the high resistance impedance layer and an edge of the non-equipotential first metal in a horizontal direction perpendicular to the vertical direction, is larger than a size of a random defect.

### CROSS-REFERENCE TO RELATED APPLICATION

This application claims the priority benefit of Taiwan application serial no. 113140107, filed on Oct. 22, 2024. The entirety of the above-mentioned patent application is hereby incorporated by reference herein and made a part of this specification.

### BACKGROUND

### Technical Field

The present invention relates to a semiconductor device, and in particular, to a semiconductor device and a method of forming the same.

### Description of Related Art

During the semiconductor wafer manufacturing process, due to the influence of various factors such as equipment, materials, operations, etc., randomly generated defects inevitably appear on the wafer. These defects are called random defects. These defects may be material defects, defects caused by equipment failure, defects caused by improper process parameters, etc. These defects may cause instability in chip performance, electrical deviations, reduced chip reliability and other problems. These defects may even render the chip completely unusable. Therefore, the control and prevention of these random defects are very important in the semiconductor manufacturing process.

Especially for semiconductor devices comprising high resistance impedance layers, the control and prevention of random defects deserves more attention. This is because in this semiconductor device, a high resistance impedance layer is often formed between the gate and the first metal structure (often referred to as M1), and a cap layer is also formed on the high resistance impedance layer, the original thickness of the dielectric layer under the first metal structure is reduced from the original distance in the vertical direction between the bottom surface of the first metal structure and the top surface of the gate to the distance between the bottom surface of the first metal structure and the top surface of the cap layer in the vertical direction.

In this structure where the thickness of the dielectric layer below the first metal structure has been reduced, if there is a random defect on the top surface of the gate, such as a metal precipitation produced by the metal gate, or remaining defective particles due to chemical mechanical polishing etc., will cause the subsequently forming layers, as such the dielectric layer, the high resistance impedance layer, cap layer, etc., after the forming of the gate. This protrusion brings the high resistance impedance layer closer to the first metal structure, thereby greatly increasing the probability of the short circuit or even the burnt out due to the excessive voltage.

### SUMMARY

Based on the above problems, the present invention provides a semiconductor device and a method for forming the same, so as to reduce the negative impact on electrical properties caused by the existence of random defect while the high resistance impedance layer exists between the gate and the first metal structure.

An embodiment of the present invention provides a semiconductor device, comprising a high resistance impedance layer between a gate and a first metal structure in a vertical direction, wherein the first metal structure comprises at least one equipotential first metal and at least one non-equipotential first metal, wherein the equipotential first metal and the high resistance impedance layer have the same potential, the non-equipotential first metal and the high resistance impedance layer have different potentials, and the non-equipotential first metal and the high resistance impedance layer do not overlap in the vertical direction, and a minimum distance, between a edge of the high resistance impedance layer and a edge of the non-equipotential first metal in a horizontal direction, the minimum distance is larger than a size of a random defect, wherein the horizontal direction is perpendicular to the vertical direction.

An embodiment of the present invention provides a method of forming a semiconductor device, comprising: forming a high resistance impedance layer between a gate and a first metal structure in the vertical direction, wherein the first metal structure comprises at least one equipotential first metal and at least one non-equipotential first metal, wherein the equipotential first metal and the high resistance impedance layer have the same potential, the non-equipotential first metal and the high resistance impedance layer have different potentials, and the non-equipotential first metal and the high resistance impedance layer do not overlap in the vertical direction, and a minimum distance, between a edge of the high resistance impedance layer and a edge of the non-equipotential first metal in a horizontal direction, the minimum distance is larger than a size of a random defect, wherein the horizontal direction is perpendicular to the vertical direction.

In an embodiment of the disclosure, the high resistance impedance layer comprises TiN or TaN.

In an embodiment of the disclosure, the equipotential first metal overlaps the high resistance impedance layer in the vertical direction.

In an embodiment of the disclosure, the size of the random defect is determined by a statistical calculation.

In an embodiment of the disclosure, the minimum distance is greater than a maximum size of the random defect.

In an embodiment of the disclosure, the minimum distance is greater than a maximum size of the random defect plus one or more standard deviation sizes.

In an embodiment of the disclosure, the minimum distance is greater than an average size of the random defect plus one or more standard deviation sizes.

In an embodiment of the disclosure, the minimum distance is from 100 nm to 260 nm.

In an embodiment of the disclosure, a cap layer on the high resistance impedance layer is further comprised.

In an embodiment of the disclosure, the cap layer comprises SiN or TiN.

Based on the above, the present invention provides a semiconductor device and a method of forming the same. By disposing the non-equipotential first metal and the high resistance impedance layer in the vertical direction without overlapping, and disposing the non-equipotential first metal and the high resistance impedance layer with a minimum distance, larger than the size of random defect, in the horizontal direction, to solve problems such as open circuits or burnt outs caused by random defect causing protrusion in subsequent deposition layers.

In order to make the above-mentioned features and advantages of the present invention more obvious and easy to understand, the following embodiments accompanying detail description and drawings are provided below.

### BRIEF DESCRIPTION OF THE DRAWINGS

FIGS. 1A to 1C are cross-sectional diagrams of a method of forming a semiconductor device A according to an embodiment of the present invention.

FIG. 2 is a cross-sectional diagram of semiconductor device A with a random defect DR.

### DESCRIPTION OF THE EMBODIMENTS

The following examples are described in detail with the accompanying drawings, but the provided examples are not intended to limit the scope of the disclosure. In order to facilitate understanding, the same components in the following description are described with the same symbols. In addition, the drawings are for illustrative purposes only and are not drawn in full scale. In fact, the dimensions of the various features may be arbitrarily increased or reduced for clarity of discussion.

The terms “comprise”, “include”, “have”, etc. used in the description are all open terms, which means “comprising but not limited to”.

In addition, the directional terms mentioned in the description, such as “up”, “down”, etc., are only used to refer to the direction of the drawings and are not used to limit the present invention. It will be understood that “on” may be used interchangeably with “under”. When an element, such as a layer or film, is placed “on” another element, the element may be placed directly on the other element, or there is intermediate element. On the other hand, when an element is said to be placed “directly on” another element, there are no intermediate element between them.

As used herein, “about,” “approximately” or “substantially” comprises the specific value plus an acceptable range of deviations (i.e., the limitations of the measurement system) that a person with ordinary skill in the art can determine. For example, “about” may mean within one or more standard deviations of the specific value, or within ±30%, ±20%, ±10%, ±5%. Furthermore, “about”, “approximately” or “substantially” used in the description can be used to select a more acceptable deviation range or standard deviation based on optical properties, etching properties or other properties, and one standard deviation does not apply to all properties.

The terminology used herein is used only to describe illustrative embodiments and does not limit the disclosure. In such cases, the singular comprises the plural unless the context dictates otherwise.

Various manufacturing steps described below may comprise deposition processes, removal processes, patterning processes, etc.

The deposition process refers to the process of forming one material onto another material. The techniques used for deposition may comprise spin coating, sputtering, chemical vapor deposition (CVD), physical vapor phase Deposition (PVD), plasma enhanced chemical vapor deposition (PE-CVD), atomic layer deposition (ALD), molecular beam deposition (MBD), pulse laser deposition (PLD), liquid source misted chemical deposition (LSMCD), etc., but are not limited thereto.

The removal process may comprise wet etching, dry etching, chemical mechanical planarization (CMP), etc., but is not limited thereto.

The patterning process may comprise coating photoresist, transferring the mask pattern to the photoresist by exposure, performing a development step to pattern the photoresist, transferring the pattern of the patterned photoresist to the material by etching, finally removing the material that need to be removed and photoresist, and perform cleaning and other steps, but are not limited to this.

1A to 1C are schematic cross-sectional views of a method of forming a semiconductor device A according to an embodiment of the present invention.

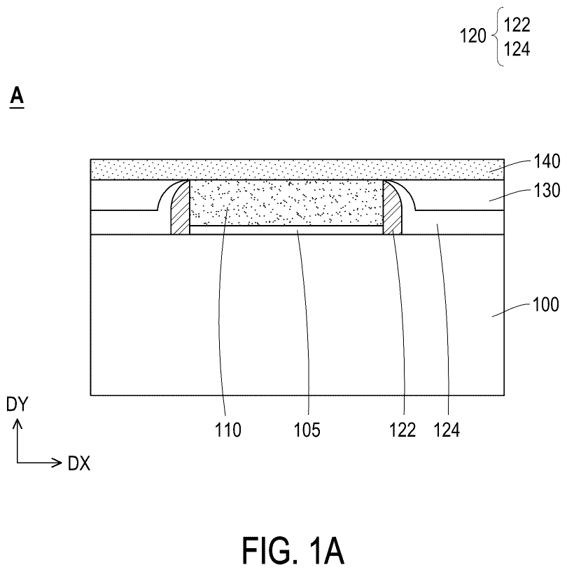

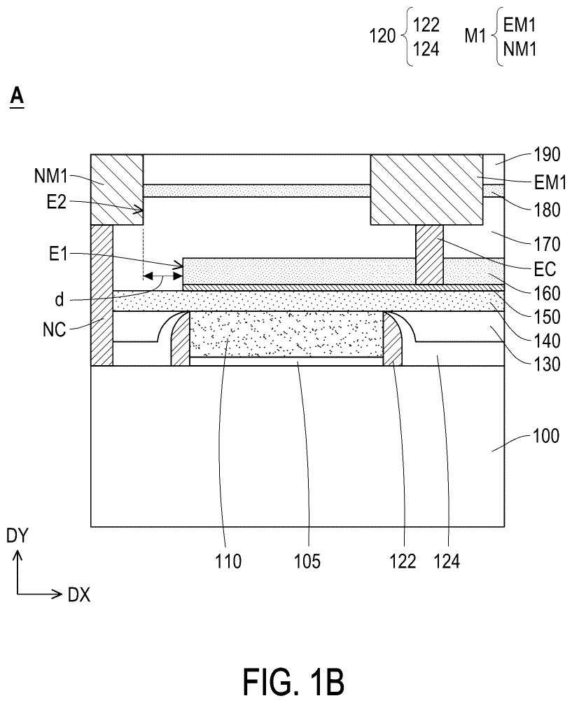

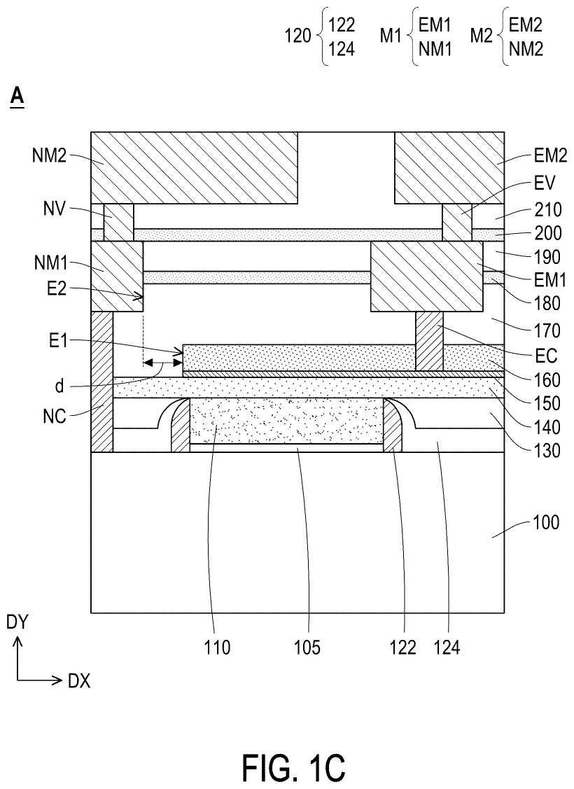

First, please refer to FIG. 1A, various methods can be used to sequentially form the gate oxide layer 105, the gate 110, the spacer 120 and the first dielectric layer 130 on the semiconductor substrate 100. The spacer 120 may be a single-layer spacer or a multi-layer spacer. As shown in FIG. 1A, the spacer 120 comprises a first spacer 122 and a second spacer 124, but is not limited thereto.

In some embodiments, the semiconductor substrate 100 may comprise silicon (Si), germanium (Ge), silicon germanium (SiGe), gallium arsenide (GaAs), indium antimonide (InSb), gallium phosphide (GaP), antimonide Gallium (GaSb), indium aluminum arsenide (InAlAs), indium gallium arsenide (InGaAs), antimony gallium phosphide (GaSbP), antimony gallium arsenide (GaAsSb), indium phosphide (InP), other III/V groups or II/VI groups semiconductor materials, but are not limited thereto.

In some embodiments, the gate oxide layer 120 may comprise silicon dioxide, rare earth metal oxides, lanthanide metal oxides, etc., such as hafnium oxide (HfO₂), hafnium silicon oxide (HfSiO₄), hafnium silicon oxynitride (HfSiON), aluminum oxide (Al₂O₃), lanthanum oxide (La₂O₃), lanthanum aluminum oxide (LaAlO), tantalum oxide, (Ta₂O₅), zirconium oxide (ZrO₂), zirconium silicon oxide (ZrSiO₄), hafnium zirconium oxide (HfZrO), yttrium oxide (Yb₂O₃), ytterbium silicon oxide (YbSiO), zirconium aluminate (ZrAlO), hafnium aluminate (HfAlO), titanium oxide (TiO₂), zirconium oxynitride (ZrON), hafnium oxynitride (HfON), zirconium silicon oxynitride (ZrSiON), hafnium silicon oxynitride (HfSiON), strontium bismuth tantalate (SrBi₂Ta₂O₉, SBT), etc., but not in this way is limited.

In some embodiments, the gate 110 may be a polysilicon gate or a metal gate. The metal gate may comprise metal, metal alloy, and/or metal silicide. For example, it may comprise aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), titanium tungsten (Ti/W) or titanium and titanium nitride (Ti/TiN) and other metal materials, but not limited to this.

In some embodiments, the spacers 120 may comprise silicon oxide, high temperature oxide (HTO), silicon nitride, silicon nitride (HCD-SiN) forming from hexachlorodisilane (Si₂Cl₆), silicon oxide-silicon nitride-silicon oxide (ONO), nitrogen-doped silicon carbide (SiCN) and other materials, but are not limited to this.

Then, through various comprehensive planarization processes, such as chemical mechanical polishing (CMP), a second dielectric layer 140 is formed on the first dielectric layer 130, as shown in FIG. 1A.

Next, referring to FIG. 1B, various methods can be used to form the high resistance impedance layer 150 and the cap layer 160 on the second dielectric layer 140.

In some embodiments, the high resistance impedance layer 150 may comprise TaN or TiN, but is not limited thereto. Any high resistance impedance layer material that can be used or developed in the future can be used in the present invention.

In some embodiments, the cap layer 160 may comprise SiN or TiN, but is not limited thereto. Any cap layer material that can be used or developed in the future can be used in the present invention.

Next, as still shown in FIG. 1B, the third dielectric layer 170, the fourth dielectric layer 190, the first metal structure M1 and the contact plugs EC and NC are formed in various ways and in various formation sequences. If necessary, a first etching stop layer 180 may also be formed therein as shown in FIG. 1B to facilitate the formation of the semiconductor device A.

Please continue to refer to FIG. 1B, in which the first metal structure M1 comprises at least one equipotential first metal EM1 and at least one non-equipotential first metal NM1, the equipotential first metal EM1 and the high resistance impedance layer 150 are at the same potential, and the non-equipotential first metal NM1 and the high resistance impedance layer 150 are at unequal potentials; the equipotential first metal EM1 can be electrically connected to the high resistance impedance layer 150 through the contact plug EC; the non-equipotential first metal NM1 can be electrically connected to the material layer outside the high resistance impedance layer 150 through the contact plug NC. For example, as shown in FIG. 1B, the non-equipotential first metal NM1 can be electrically connected to the semiconductor substrate 100 through the contact plug NC, but is not limited thereto. The non-equipotential first metal NM1 can be electrically connected to any material layer other than the high resistance impedance layer 150 based on the requirement of the designed electrical connection.

Furthermore, as shown in FIG. 1B, the non-equipotential first metal NM1 and the high resistance impedance layer 150 do not overlap in the vertical direction DY. That is, the non-equipotential first metal NM1 does not exist above the high resistance impedance layer 150.

In addition, as shown in FIG. 1B, the equipotential first metal EM1 may overlap with the high resistance impedance layer 150 in the vertical direction DY. That is, the equipotential first metal EM1 may be above the high resistance impedance layer 150.

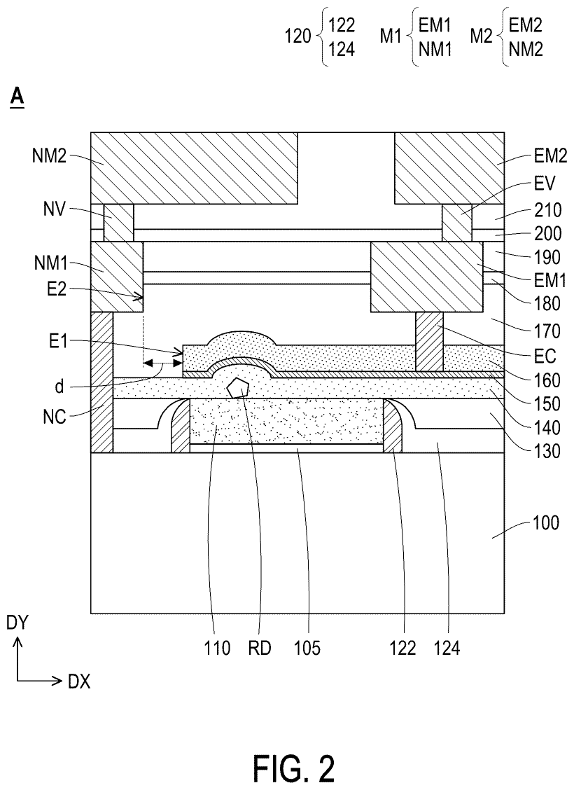

Moreover, as shown in FIG. 1B, there is a minimum distance d between the edge E1 of the high resistance impedance layer 150 and the edge E2 of the non-equipotential first metal NM1 in the horizontal direction DX, the horizontal direction DX and the vertical direction DY are perpendicular to each other, and the minimum distance d is larger than the size of the random defect RD as shown in FIG. 2.

Since the non-equipotential first metal NM1 is no longer above the high resistance impedance layer 150 in the vertical direction DY, and the distance d between non-equipotential first metal NM1 and the high resistance impedance layer 150 is greater than the size of the random defect RD. Therefore, even if the random defect RD exists in the semiconductor device A, the random defect RD, the protrusion in subsequent deposited layers, for example, as shown in FIG. 2, the protrusion of the high resistance impedance layer 150 and the cap layer 160, will not too close and even physically contact with the non-equipotential first metal NM1. The circuit short circuit or the burnt out circuit due to the unable voltage will not happen.

That is to say, the present invention disposes the non-equipotential first metal NM1 outside the vertical direction DY of the high resistance impedance layer 150, that is, the non-equipotential first metal NM1 and the high resistance impedance layer 150 do not overlap in the vertical direction. DY, and there is also a minimum distance d, larger than the size of the random defect RD, in the horizontal direction DX between the non-equipotential first metal NM1 and the high resistance impedance layer 150, to solve the electrical negative effects problem of protrusion of the subsequent deposition layer caused by the random defect RD.

The size of the random defect RD is obtained by a statistical calculation.

In some embodiments, the minimum distance d may be greater than a maximum size of the random defect RD to avoid problems such as electrical connection between the non-equipotential first metal NM1 and the high resistance impedance layer 150 due to the presence of the random defect RD.

In some embodiments, the minimum distance d may also be greater than a maximum size of the random defect RD plus one or more standard deviation sizes to more completely avoid electrical problems caused by the existence of the random defect RD.

However, the minimum distance d cannot be increased without limit. The density of semiconductor devices A must be taken into consideration. Especially in advanced processes where device concentration is more demanding, the minimum distance d must comply with the design spec of the devices.

In some embodiments, the minimum distance d may also be greater than an average size of the random defects RD plus one or more standard deviation sizes to reduce electrical problems caused by the existence of the random defects RD.

The selection of the above minimum distance d depends on the importance of the semiconductor device A, its size spec range, the probability of occurrence of random defects RD, the degree of negative impact caused by random defects RD hopping to avoid, and other factors.

In some embodiments, the minimum distance d may be from about 100 nm to about 260 nm; more preferably, it can be about 120 nm to about 250 nm; optimally, it can be about 140 nm to about 240 nm, but it is not limited to the above range. The best choice must be made according to the size of the actual semiconductor device A.

Next, please refer to FIG. 1C, various methods and various formation sequences can be used to form the second etch stop layer 200, the fifth dielectric layer 210, and the via plugs EV, NV and the second metal structure M2 on the fourth dielectric layer 190 and the first metal structure M1. The second metal structure M2 comprises an equipotential second metal EM2 and a non-equipotential second metal NM2. The equipotential second metal EM2 and the high resistance impedance layer 150 are of equal potential, and the non-equipotential second metal NM2 and the high resistance impedance layer 150 are of unequal potential. The equipotential second metal EM2 can be electrically connected to the equipotential first metal EM1 through the via plug EV; the non-equipotential second metal NM2 can be electrically connected to the non-equipotential first metal NM1 through the via plug NV.

Since the second metal structure M2 has already some distance away from the high resistance impedance layer 150 and the cap layer 160, it can be formed in the vertical direction DY of the high resistance impedance layer 150 and the cap layer 160 as required. If there is a random defect RD exist in the semiconductor device A, unless it is an extreme phenomenon, such as a super large random defect RD outside of statistics, it should not have a serious impact on the second metal structure M2. Therefore, the second metal structure M2 and the high resistance impedance layer 150 can overlap in the vertical direction DY.

In some embodiments, the first dielectric layer 130, the second dielectric layer 140, the third dielectric layer 170, the fourth dielectric layer 190 and the fifth dielectric layer 210 mentioned above may comprise, for example, nitride, such as silicon nitride (SiN), silicon oxynitride (SiON); carbides, such as nitrogen-doped silicon carbide (SiCN); oxides, such as silicon dioxide (SiO₂), tetraethoxysilane (TEOS), borosilicate glass (BSG), phosphoric silicate glass (PSG), borophosphorus silicate glass (BPSG); low dielectric constant oxides, such as carbon-doped oxides, SiCOH; or other suitable dielectric materials developed in the future.

In some embodiments, the above-mentioned contact plugs EC, NC, the equipotential first metal EM1, the equipotential second metal EM2, the via plugs EV, NV, the first metal structure M1, the second metal structure M2, the non-equipotential first metal NM1 and the non-equipotential second metal NM2 may be formed of conductive materials, such as copper (Cu), tungsten (W), aluminum (Al), titanium (Ti), nickel (Ni), platinum (Pt), Ruthenium (Ru), cobalt (Co) or their alloys, or other suitable conductive materials developed in the future.

In addition, although not shown in the drawings, in some embodiments, each of the contact plugs EC, NC, the equipotential first metal EM1, the equipotential second metal EM2, the via plugs EV, NV, the first metal structure M1, the second metal structure M2, the non-equipotential first metal NM1, and the non-equipotential second metal NM2 may additionally comprise a barrier liner surrounding its side surface and lower surface to prevent or reduce atoms diffuse into and out of the conductive material in the metal interconnect layered structure. The barrier liner may comprise, but is not limited to, titanium, titanium nitride, tantalum, or tantalum nitride.

In some embodiments, the first etch stop layer 180 and the second etch stop layer 200 may respectively comprise nitride or carbide, but are not limited thereto. For Example, they may comprise silicon nitride (SiN), silicon dioxide (SiO2), nitrogen silicon oxide (SiON), nitrogen-doped silicon carbide (SiCN), SiCxHz (BLoK™), SiNwCxHz (NBLoK™), where each of w, x, y, and z independently has a value greater than 0 and less than 0.75.

Based on the above, the present invention provides a semiconductor device and a method of forming the same. By disposing the non-equipotential first metal and the high resistance impedance layer in the vertical direction without overlapping, and a minimum distance between the resistance layer and the non-equipotential first metal is larger than the size of random defects, the problems such as open circuits or burnt outs caused by random defects causing protrusions in subsequent deposition layers may be solved.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A semiconductor device, comprising:
a high resistance impedance layer between a gate and a first metal structure in a vertical direction, wherein
the first metal structure comprises at least one equipotential first metal and at least one non-equipotential first metal, wherein the equipotential first metal and the high resistance impedance layer have the same potential, the non-equipotential first metal and the high resistance impedance layer have different potentials, and the non-equipotential first metal and the high resistance impedance layer do not overlap in the vertical direction, and
a minimum distance, between an edge of the high resistance impedance layer and an edge of the non-equipotential first metal in a horizontal direction, the minimum distance is larger than a size of a random defect, wherein the horizontal direction is perpendicular to the vertical direction.

2. The semiconductor device according to claim 1, wherein the high resistance impedance layer comprises TiN or TaN.

3. The semiconductor device according to claim 1, wherein the equipotential first metal overlaps the high resistance impedance layer in the vertical direction.

4. The semiconductor device according to claim 1, wherein the size of the random defect is obtained by a statistical calculation.

5. The semiconductor device according to claim 1, wherein the minimum distance is greater than a maximum size of the random defect.

6. The semiconductor device according to claim 1, wherein the minimum distance is greater than a maximum size of the random defect plus one or more standard deviation sizes.

7. The semiconductor device according to claim 1, wherein the minimum distance is greater than an average size of the random defects plus one or more standard deviation sizes.

8. The semiconductor device according to claim 1, wherein the minimum distance is from 100 nm to 260 nm.

9. The semiconductor device according to claim 1, further comprising a cap layer on the high resistance impedance layer.

10. The semiconductor device according to claim 9, wherein the cap layer comprises SiN or TiN.

11. A method of forming a semiconductor device, comprising:
forming a high resistance impedance layer between a gate and a first metal structure in the vertical direction, wherein
the first metal structure comprises at least one equipotential first metal and at least one non-equipotential first metal, wherein the equipotential first metal and the high resistance impedance layer have the same potential, the non-equipotential first metal and the high resistance impedance layer have different potentials, and the non-equipotential first metal and the high resistance impedance layer do not overlap in the vertical direction, and
a minimum distance, between an edge of the high resistance impedance layer and an edge of the non-equipotential first metal in a horizontal direction, the minimum distance is larger than a size of a random defect, wherein the horizontal direction is perpendicular to the vertical direction.

12. The method of forming a semiconductor device according to claim 11, wherein the high resistance impedance layer comprises TiN or TaN.

13. The method of forming a semiconductor device according to claim 11, wherein the equipotential first metal overlaps the high resistance impedance layer in the vertical direction.

14. The method of forming a semiconductor device according to claim 11, wherein the size of the random defect is obtained by a statistical calculation.

15. The method of forming a semiconductor device according to claim 11, wherein the minimum distance is greater than a maximum size of the random defect.

16. The method of forming a semiconductor device according to claim 11, wherein the minimum distance is greater than a maximum size of the random defect plus one or more standard deviation sizes.

17. The method of forming a semiconductor device according to claim 11, wherein the minimum distance is greater than an average size of the random defects plus one or more standard deviation sizes.

18. The method of forming a semiconductor device according to claim 11, wherein the minimum distance is from 100 nm to 260 nm.

19. The method of forming a semiconductor device according to claim 11, further comprising a cap layer on the high resistance impedance layer.

20. The method of forming a semiconductor device according to claim 19, wherein the cap layer comprises SiN or TiN.
